(19) United States
(12) Patent Application Publication
(10) Pub. No.: US 2010/0083762 A1
(43) Pub. Date: Apr. 8, 2010

(54) FABRICATION AND USE OF SUBMICRON WIDE SUSPENDED STRUCTURES

(76) Inventors: Stephane Evoy, Edmonton (CA); Lee M. Fischer, Edmonton (CA); Csaba Guthy, Edmonton (CA)

Correspondence Address: Lambert Intellectual Property Law, Suite 200, 10328 - 81 Avenue, Edmonton, AB, T6E 1X2, CA

(21) Appl. No.: 12/244,419

(22) Filed: Oct. 2, 2008

(51) Int. Cl. G01H 13/00; B32B 18/00; G03F 7/20

(52) U.S. Cl. 73/579; 428/210; 430/323

(57) ABSTRACT

A method of fabrication of submicron wide suspended structures. The method includes depositing a layer of glassy material under tensile stress on crystalline silicon, patterning the layer of glassy material with a masking layer having a pattern, the masking layer protecting the layer of glassy material along the pattern, selectively removing the layer of glassy material in areas of the layer of glassy material not protected by the masking layer; and anisotropically etching the crystalline silicon to create at least a pit extending into the crystalline silicon and at least partially under the layer of glassy material to release a suspended structure comprising glassy material.

### TECHNICAL FIELD

Fabrication of sub-micron structures, and their use.

### BACKGROUND

Current nanofabrication techniques are usually limited to ˜100 nm wide devices. In addition, these standard processes usually require a critical point drying step to insure acceptable yield. Critical point drying is known to contaminate the surface of the fabricated structure, rendering it useless for applications requiring clean surfaces. Techniques for forming such small structures tend to have low yield.

### SUMMARY

In an embodiment, there is provided a new method of fabrication of submicron wide suspended structures. The method may include depositing a layer of glassy material under tensile stress on crystalline silicon, patterning the layer of glassy material with a masking layer having a pattern, the masking layer protecting the layer of glassy material along the pattern, selectively removing the layer of glassy material in areas of the layer of glassy material not protected by the masking layer; and anisotropically etching the crystalline silicon to create at least a pit extending into the crystalline silicon and at least partially under the layer of glassy material to release a suspended structure comprising glassy material. Sub-micron wide suspended structures may be used for example in bio-assays, taking advantage of the dependence of the resonant frequency of the structures on the mass of the structures. The resulting structures and a method of use of the structures are also claimed. These and other aspects of the method are set out in the claims, which are incorporated here by reference.

### BRIEF DESCRIPTION OF THE FIGURES

Embodiments will now be described with reference to the figures, in which like reference characters denote like elements, by way of example, and in which:

FIG. 1 illustrates method steps of an embodiment of a method of fabricating submicron wide suspended structures;

FIG. 2 illustrates particularized method steps of the embodiment of FIG. 1;

FIGS. 3A-3C show steps in a bio-assay method using submicron wide suspended structures; and

FIG. 4 shows results of a resonant frequency test for a loaded submicron wide suspended structure.

### DETAILED DESCRIPTION

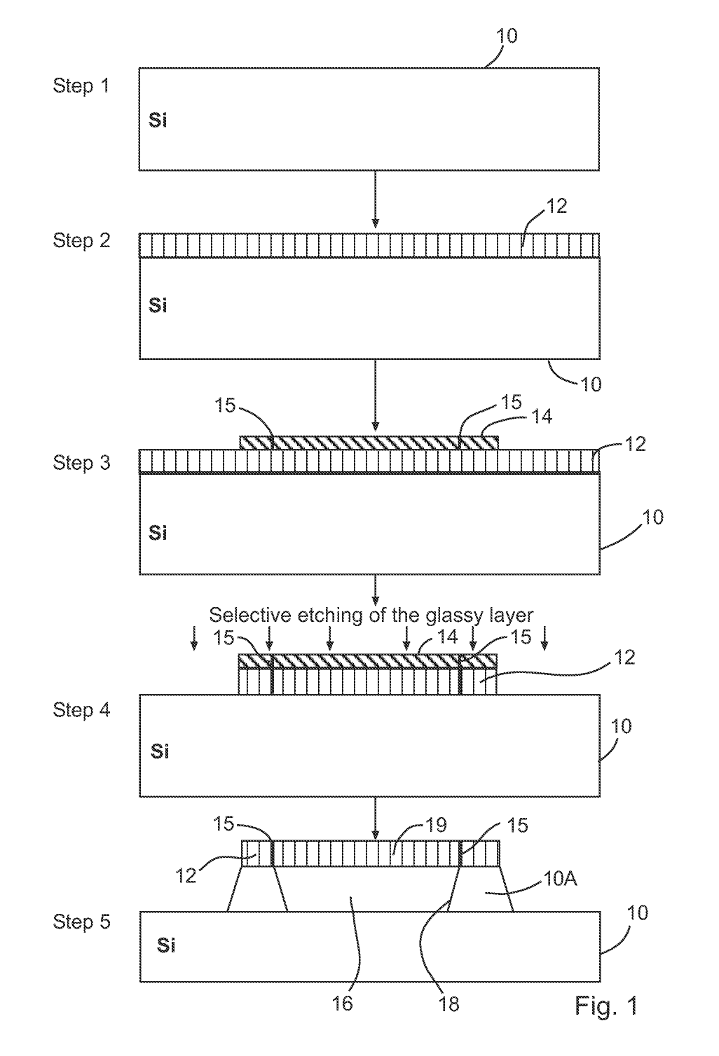

Referring to FIG. 1, wafers 10 of single-crystal silicon (100) or (110) are used as substrates (step 1). A layer of any glassy material 12 under tensile stress is deposited on the substrate 10 (step 2). Any lithography technique (such as photolithography and electron beam lithography) is used to pattern the surface of the glassy layer 12 with a masking layer 14 that will specifically protect the glassy layer 12 along the pattern to be created (step 3). The pattern may be any desired shape, such as an L shaped structure in plan view. Any etching technique offering high etching selectivity of the glassy layer 12 over the masking layer 14 is then employed to transfer the pattern into the glassy layer (step 4). If need be, the masking layer 14 may then be removed using appropriate acid or solvent. An etchant offering high etching selectivity of the silicon {100} and {110} compared to the {111} plane, such as potassium hydroxide (KOH), tetramethylammonium hydroxide (TMAH), or ethylenediamine-pyrocatechol-water (EDP), is used to aniisotropic etch the silicon substrate 10 This anisotropic procedure results in the creation of a pit 16 whose walls 18 are oriented along the {111} planes. Given the finite angle that this plane makes with the surface layer 12, this will also result in the release of the suspended structure 19 formed out of the glassy layer 12 (step 5).

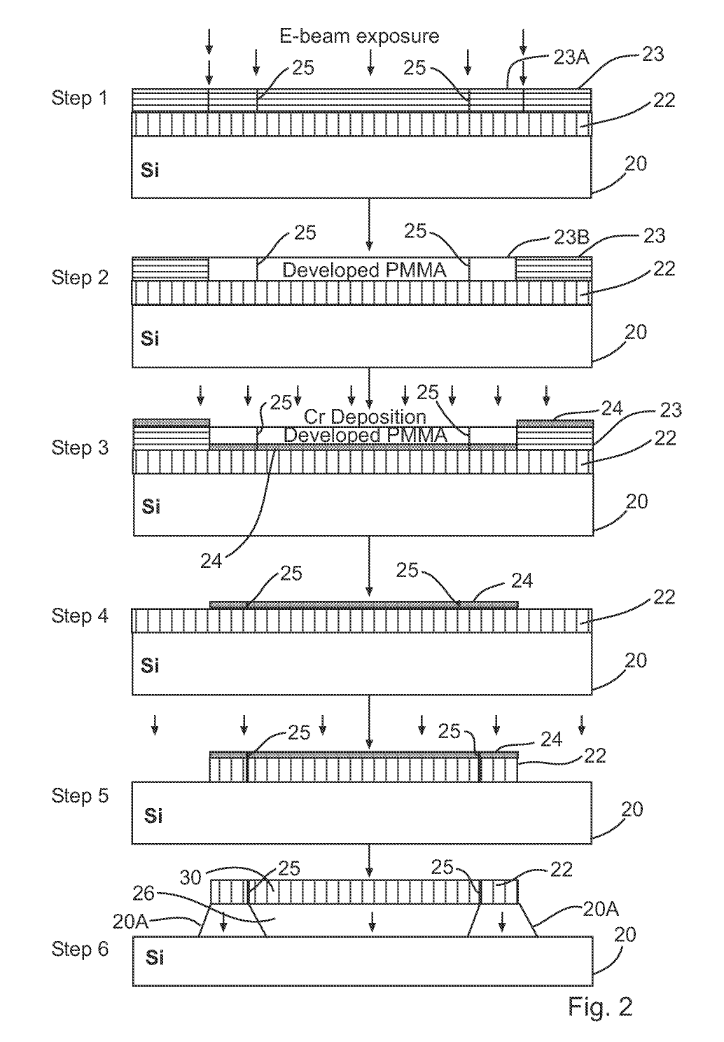

Referring to FIG. 2, a wafer 20 (500 um thick, 100 mm diameter but other dimensions may be used according to the application) of single-crystal silicon (100) is used as a crystalline silicon substrate. The wafer 20, if not already clean, may be cleaned as for example in a Piranha mixture (3:1 sulfuric acid: hydrogen peroxide) for 20 mins. A SiCN glassy layer 22 is deposited via for example chemical vapor deposition on the wafer 20. Chemical vapor deposition may be carried out, to give a non-limiting example, in a Trion Technology Orion plasma-enhanced chemical vapor deposition (PECVD) system using ammonia (NH₃), nitrogen (N₂) and diethylsilane (DES) at a pressure of P=500 mTorr, temperature of T=300° C., and power density of p=0.63 W/cm² with a gas flow ratio of 4:1 NH₃:DES. A deposition time of 100 s results in a deposition of 50 nm layer 22 of SiCN. The SiCN-coated wafer 20 is then annealed in a MiniBrute 3-zone tube furnace at 500° C. for 8 h under N₂ gas flow of 100 sccm to drive off hydrogen and maximize tensile stress (˜400 MPa). This produces a wafer 20 with a glassy layer 22 under tensile stress. The wafer 20 is then treated with another piranha clean, in preparation for resist application. These wafer 20 is cleaved into 1.5×1.5 cm squares, and spin-coated with a bilayer of polymethyl methacrylate (PMMA) of molecular weights of 950 and 495, respectively and baked at 180° C. for 20 mins after each layer to produce a resist layer 23. Patterning of the resist layer 23 is performed using a Raith 150 electron-beam lithography system using a 20-um aperture, an accelerating voltage of 10 kV, and an areal dose of 130 uC/cm² for the support structure and a line dose of 2000 pC/cm for the resonator beam. These steps produce a patterned resist 23A on a glassy layer 22 on top of the wafer 20 (step 1).

Following development of the exposed resist for example in 1:3 MIBK:IPA for 40s (step 2) to produce a developed resist 23B, masking layer 24 is deposit on the glassy layer 22 where the resist 23 has been developed and on the resist 23 where it is not developed. The masking layer 24 may be deposited for example using an electron-beam evaporator to deposit a 30 nm chromium masking layer 24 (step 3). In the unexposed areas this chrome layer 24 is lifted off or otherwise removed, as for example by immersing the samples in acetone at 60° C. for 30 mins (step 4). An etcher such as a Trion Technology Phantom II reactive ion etcher (RIE) is used to anisotropically etch the Cr-patterned SiCN glassy layer 22 (for example for 40 s for 50 nm of SiCN), using for example a 4:1 SF₆:O₂ plasma recipe (step 5). The Cr mask 24 is removed as for example by using a Cr-etch for 20 mins. The suspended structure 30 is then released by etching of the silicon substrate 20 to create a pit 26 under the glassy layer 22. The etching may be carried out for example by potassium hydroxide (35%) saturated with IPA at 75° C. to release the nanostructure 30 (step 6). A 2-3 mins immersion in that solution creates 6 μm deep pits under the suspended structure 30. The samples are rinsed in DI water and dried under a gentle nitrogen flow. Resonators made in this manner may have varying lengths and sub-micron width, and for example have had lengths from 10 μm to 50 μm, thickness (measured perpendicular to the substrate) in the order of 30 nm, width in the order of 35 nm-400 nm, and less than 50 nm undercut at their anchoring point, while maintaining a 3-6 μm gap with the substrate.

In FIGS. 1 and 2, the lines 15 and 25 show three-dimensional structure. At the end points of the suspended structures, portions of the substrate 10, 20 that are not removed by etching form support pads 10A, 20A for the resonator portion. The resonator portions 19, 30 of the structure are narrower out of the plane of the figures than the width of the glassy layers 12, 22 at the support pads 10A, 20A. The lines 15 and 25 respectively show the width of the resonator portions 19, 30 that extend out of the plane of the figure. Additional support pads (not shown) may be provided at the distal ends of the resonator portions 19, 30.

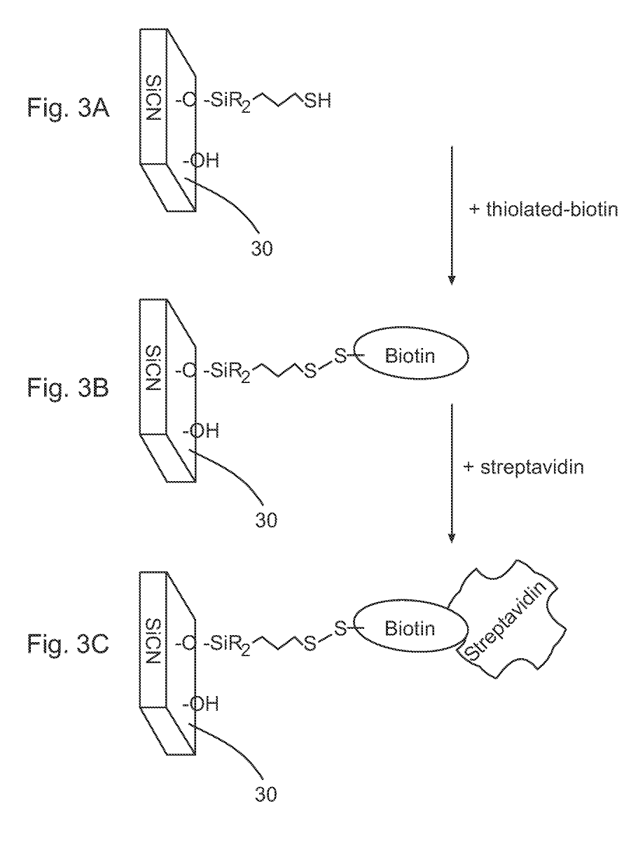

Submicron wide suspended structures made according to the methods of FIG. 1 or 2 may be used for example in a bio-assay method, taking advantage of the dependence of the resonant frequency of the suspended structures on the mass of the structures and whatever is attached to the structures. Thus, as illustrated in FIGS. 3A-3C, sub-micron wide suspended structures 30 made in accordance with the method steps of FIG. 2 are coated with MPTMS (ie silanized with mercaptopropyl trimethyloxysilane, but other materials could be used) using for example vapor deposition to form an adhesion layer (FIG. 3A) onto which for example biotin is immobilized (FIG. 3B). A bio-molecule such as streptavidin protein may then be attached to the biotin for detection (FIG. 3C). Variation of the resonant frequency of the sub-micron wide suspended structures 30 with the mass of the structures, including material adhered to the structures 30, may be used to assay the adhered material. The resonant frequency of the structures 30 may be detected for example by interferometry.

Detection of the resonant frequency of the sub-micron wide suspended structure 30 may be carried out by mounting structures 30, which could be an array of structures 30, on a piezoelectric stage mounted inside a vacuum chamber. The piezoelectric stage may be actuated by the output of a spectrum analyzer. A laser, such as a He—Ne laser with a suitable output wavelength, is focused onto the structure 30 through a microscope objective. When actuated at resonance, relative motion of the structure 30 with respect to the underlying silicon substrate 20 modulates the reflected signal through interferometric effects. The modulated signal is reflected back through the microscope objective. A beam splitter is employed to divert the reflected signal to a photodetector, whose output is fed to the input of the spectrum analyzer. The spectrum analyzer may be operated to sweep through a range of frequencies and detect the resonant frequency of the structure 30, plus load.

The mass sensitivity Δm of a resonator may be obtained from Δm=m/Q where m is the mass of the resonator and Q is the quality factor. With structures 30 having dimensions of about 35 nm thickness, 430 nm width and 40-50 μm long, m has values of about 1.4-1.8 ag. With a Q of about 5000 after silane adsorption, the structures 30 may therefore resolve masses having a Δm of approx. 0.4 fg. As masses are added to the structures 30, the resonant frequency decreases. The frequency shift Δf is related to the added mass Δm as follows: Δm/Δf=2 m/fₒ (equation 1) where m is the mass of the unloaded resonator and fₒ is the resonant frequency of the unloaded resonator. Equation 1 may be used to determine the mass of added material, such as a sample to be assayed.

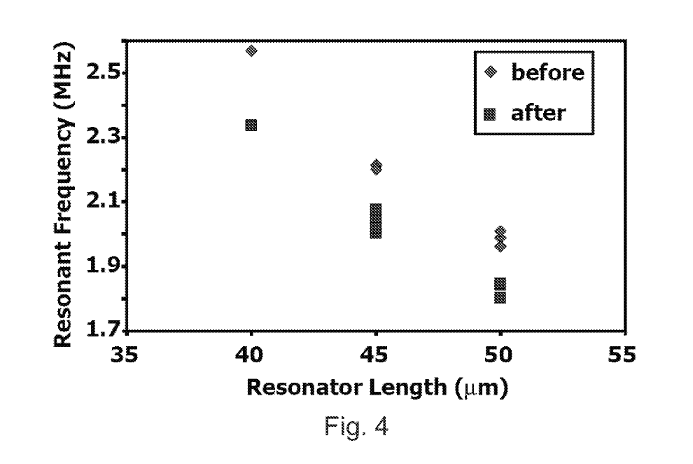

FIG. 4 plots the resonant frequency of a set of structures 30 before and after attachment of MPTMS linker, biotin and streptavidin. The frequency shifts and total added masses reported are the cumulative result of the added MPTMS, biotin and streptavidin. Similar results may be obtained for addition of the binder MPTMS and biotin alone and the mass of the streptavidin determined from equation 1. Any material capable of being immobilized on the structure 30 may be assayed. The structures 30 also have application wherever suspended structures are required, such as cantilever switches on NEMS devices. The structures 30 may be part of an assay device with arrays of structures 30 that can be individually targeted by a scanning laser.

Immaterial modifications may be made to the embodiments described here without departing from what is covered by the claims. In the claims, the word “comprising” is used in its inclusive sense and does not exclude other elements being present. The indefinite article “a” before a claim feature does not exclude more than one of the feature being present. Each one of the individual features described here may be used in one or more embodiments and is not, by virtue only of being described here, to be construed as essential to all embodiments as defined by the claims.

1. A method of fabrication of submicron wide suspended structures, the method comprising:
depositing a layer of glassy material under tensile stress on crystalline silicon;
patterning the layer of glassy material with a masking layer having a pattern, the masking layer protecting the layer of glassy material along the pattern;
selectively removing the layer of glassy material in areas of the layer of glassy material not protected by the masking layer; and
anisotropically etching the crystalline silicon to create at least a pit extending into the crystalline silicon and at least partially under the layer of glassy material to release a suspended structure comprising glassy material.

2. The method of claim 1 in which the crystalline silicon comprises a wafer of single-crystal silicon (100) or (110).

3. The method of claim 2 in which anisotropically etching the crystalline silicon comprising etching with an etchant offering high etching selectivity of silicon {100} plane and {110} plane compared to the {111} plane to create walls of the pit oriented along {111} planes.

4. The method of claim 3 in which the etchant used for anisotropically etching is one or more of potassium hydroxide (KOH), tetramethylammonium hydroxide (TMAH), or ethylenediamine-pyrocatechol-water (EDP).

5. The method of claim 1 in which patterning is carried out by lithography.

6. The method of claim 1 in which removing the layer of glassy material is carried out using an etching technique with etching selectivity of the glassy layer over the masking layer to transfer the pattern into the glassy layer.

7. The method of claim 1 further comprising, after selectively removing the glassy layer, removing the masking layer.

8. A submicron wide suspended structure formed by claim 1.

9. An assay method, comprising:
preparing a sub-micron wide suspended structure according to the method steps of claim 1;
immobilizing a sample on the sub-micron wide suspended structure; and
detecting the resonant frequency of the sub-micron wide suspended structure.
